(19) United States
(12) Patent Application Publication
(10) Pub. No.: US 2004/0072426 A1
(43) Pub. Date: Apr. 15, 2004

(54) Process chamber for manufacturing a smiconductor device

(76) Inventor: Soon-Jong Jung, Suwon-City (KR)

Correspondence Address: VOLENTINE FRANCOS, P.L.L.C., Suite 150, 12200 Sunrise Valley Drive, Reston, VA, 20191, US

(21) Appl. No.: 10/620,589

(22) Filed: Jul. 17, 2003

(30) Foreign Application Priority Data
Aug. 2, 2002 (KR) 2002-45912

(51) Int. Cl. H01L 21/302; H01L 21/461

(52) U.S. Cl. 438/689

(57) ABSTRACT

A process chamber of semiconductor fabrication equipment includes a vessel in which a process gas is supplied, an upper electrode installed in an upper part of the vessel and to which power is applied, a shield ring extending alongside the upper electrode for insulating the upper electrode, a lower electrode disposed under the upper electrode as spaced from the upper electrode and to which power is applied to convert the process gas to plasma, an electrostatic chuck sitauted on the lower electrode and on which a wafer is received, and an insulation ring unit extending alongside the lower electrode for insulating the lower electrode. The shield ring and the insulation ring unit have a protection layer as an outer coating to prevent the shield ring and the insulation ring unit from being etched.

### BACKGROUND OF INVENTION

1. Field of the Invention

The present invention relates to the manufacturing of a semiconductor device. More specifically, the present invention relates the process chamber of plasma etching apparatus.

2. Description of Related Art

Generally, a semiconductor device is fabricated by stacking a plurality of layers on a silicon wafer, each of the layers having a circuit pattern. The circuit patterns are formed by a plurality of unit processes such as deposition, photolithography and etching processes. Moreover, there is an ever increasing demand for more highly integrated semiconductor devices. In this respect, height differences at the surface of the semiconductor wafer become more pronounced the higher the integration density becomes. Therefore, the above-mentioned unit processes must be precisely executed if a pattern having a fine pitch is to be formed on such a surface wherein a great step height exists.

To this end, plasma application processes have been used to fabricate the semiconductor devices. These processes have shown great ability to precisely process a silicon wafer, including when used to form a circuit pattern having a fine pitch on an uneven surface of a semiconductor wafer.

A process chamber for performing a plasma dry etching process, as one example of the plasma application processes, will be described below.

A conventional plasma dry etching process chamber comprises a sealed vessel in which a predetermined pressure is maintained, and an upper electrode and a lower electrode disposed in the vessel as spaced from each other. A process gas is introduced into the vessel. A power source is connected to the upper electrode and lower electrodes.

The upper electrode has a process gas supplying hole through which the process gas is supplied into the vessel. The lower electrode supports an electrostatic chuck that receives a wafer thereon. Rings formed of an insulator, such as quartz, are installed around the upper electrode and the lower electrode or along an internal wall of the vessel to electrically insulate the upper electrode and the lower electrode with each other.

A plasma dry etching process using the plasma dry etching process chamber will be described below.

First, the wafer is loaded into the vessel by a transfer arm and is placed on the electrostatic chuck. Power is then applied to the upper electrode and the lower electrode as soon as the process gas is supplied into the vessel. Therefore, an electric field is formed between the upper electrode and the lower electrode and the process gas introduced into the process chamber is activated and converted into plasma. Then, ions of the plasma etch the wafer situated on the electrostatic chuck.

However, the conventional process chamber suffers from a problem in that the ions of the plasma etch not only the wafer but also surfaces of the upper and lower electrodes and the rings installed at the side of the electrodes or at the internal walls of the outer vessel, thereby producing particles. The particles cause various problems such as lowering the operating rate of the semiconductor processing equipment and increasing wafer loss.

Furthermore, byproducts produced in the plasma dry etching process are deposited on the quartz rings, and the deposited byproducts act as a source of contaminants in the subsequent processes.

### SUMMARY OF THE INVENTION

An object of the present invention is to overcome the problems described above. It is thus an object of the present invention to provide a process chamber for manufacturing a semiconductor device, the process chamber having a protection layer on internal surfaces thereof that prevents particles from being formed therein.

In accordance with one aspect of the present invention, there is provided a process chamber of semiconductor fabrication equipment, which includes a vessel in which a process gas is supplied, an upper electrode installed in an upper part of the vessel and to which power is applied, a shield ring extending alongside the upper electrode for insulating the upper electrode, a lower electrode disposed under the upper electrode as spaced from the upper electrode and to which power is applied to convert the process gas to plasma, an electrostatic chuck sitauted on the lower electrode and on which a wafer is received, and an insulation ring unit extending alongside the lower electrode for insulating the lower electrode. The shield ring and the insulation ring unit have a protection layer as an outer coating to prevent the shield ring and the insulation ring unit from being etched.

The protection layer is preferably a layer of AlN, TiN, DLC or of Al₂O₃. The protection layer may be formed by sputtering, for example.

### BRIEF DESCRIPTION OF THE DRAWINGS

These and other features and advantages of the present invention will be readily apparent to those of ordinary skill in the art upon review of the detailed description that follows when taken in conjunction with the accompanying drawings, in which like reference numerals denote like parts, and in which:

FIG. 1 is a schematic diagram of a process chamber for fabricating a semiconductor device in accordance with the present invention.

### DETAILED DESCRIPTION OF PREFERRED EMBODIMENTS

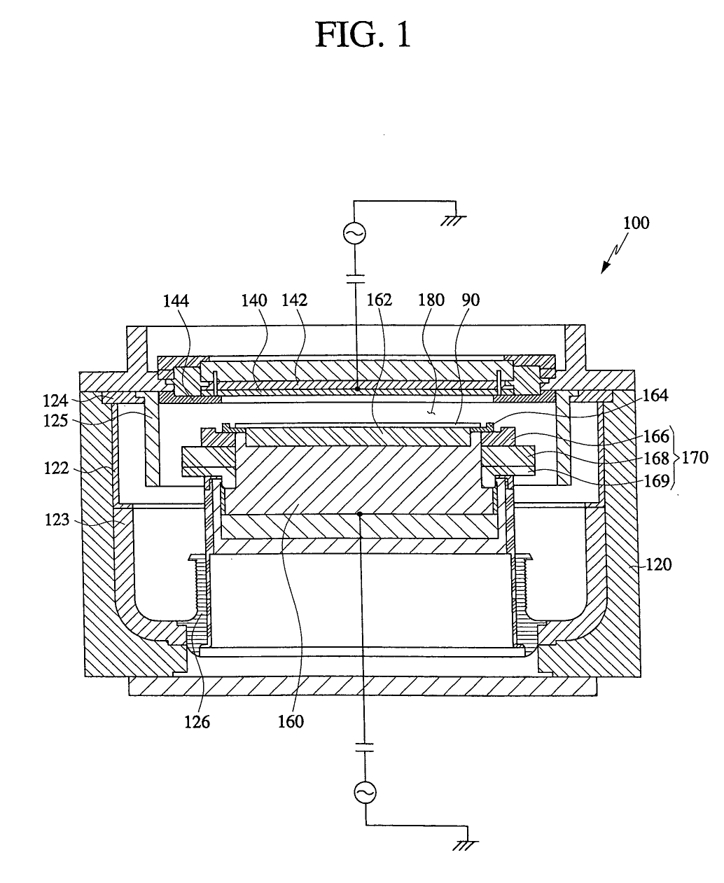

As shown in FIG. 1, a process chamber 100 according to the present invention includes an outer vessel 120 having the shape of a cylinder. An upper electrode 140 to which a power source is connected is installed in an upper part of the outer vessel 120. The upper electrode 140 has a process gas supplying hole (not shown) so that a process gas may be supplied into the vessel 120 therethrough. A cooling plate 142 is installed on an upper surface of the upper electrode 140 to control the temperature of the upper electrode 140. A shield ring 144 extends along the outer peripheral edge of the upper electrode 140 to insulate the upper electrode 140.

An outer ring 125 formed of quartz is installed at an outer edge of the shield ring 144 and a center ring 124 is installed at an outer edge of outer ring 125.

The lower electrode 160 is disposed under the upper electrode 140 as spaced from the upper electrode 140. A power source, such as a high frequency power source, is connected to the lower electrode 160. The lower electrode 160 is movable up and down by a driving means (not shown) to adjust the size of a space formed between the upper electrode 140 and the lower electrode 160. An electric field is formed in the space between the upper electrode 140 and the lower electrode 160 by applying the power to the lower electrode 160 and the upper electrode 140, whereby process gas supplied into the vessel 120 is converted to plasma. A bellows 126 is connected to the bottom of the lower electrode 160 so that it can be compressed and expanded along with the vertical movement of the lower electrode 160. Furthermore, an electrostatic chuck 162 on which a wafer 90 to be etched is received is disposed on the lower electrode 160. An insulation ring unit 170 extends along the outer periphery of the lower electrode 160 to insulate the lower electrode 160. The insulation ring unit 170 comprises a base ring 169 for insulating a lower part of the lower electrode 160, a cover ring 166 for insulating an upper part of the lower electrode 160 and an exhaust ring 168 interposed between the base ring 169 and the cover ring 166 to insulate a middle part of the lower electrode 160.

A focus ring 164 extends along the outer periphery of the electrostatic chuck 162 at an upper surface of the cover ring 166 to direct reactive ions of the plasma towards the wafer 90. The focus ring 164 is formed of aluminum Al so that it will not be etched by the ions.

The shield ring 144 for insulating the upper electrode 140 and the insulation ring unit 170 are formed of an insulator such as quartz. Preferably, the surfaces of the shield ring 144 and the insulation ring unit 170 are coated with a protection layer. Furthermore, the outer peripheral side surface and the bottom surface of the shield ring 144, and the upper surface and the outer peripheral side surface of the cover ring 166 are coated with a protection layer because those surfaces are most frequently exposed to the ions of the plasma. The protection layer is formed of Al₂O₃, AlN or TiN. The shield ring 144 and the insulation ring unit 170 may alternatively be coated with a diamond-like coating (DLC) by positioning substrates thereof in a vacuum coating chamber and depositing thereon a diamond-like composition containing carbon, silicon, oxygen, hydrogen, and fluorine using clusterless particle beams of ions, atoms, or radicals of the carbon, silicon, oxygen, hydrogen, and fluorine. The protection layer may be formed by well-known coating methods. For example, the protection layer may be formed by a sputtering method in which the coating material is deposited on a substrate based on momentum transfer by the bombardment of the substrate. The protection layer prevents the surfaces of the shield ring 144 and the insulation ring unit 170 from being etched and thereby damaged, and thus prevents the byproducts produced in the etching process from being deposited onto the surfaces of the process chamber 100.

Reference numerals 122 and 123 denote an upper masking shield 122 and a lower masking shield 123, respectively, and reference numeral 180 denotes the space where the plasma is formed.

The operation of the process chamber 100 will be described below.

First, the wafer 90 is loaded by a transfer arm on the electrostatic chuck 162 of the process chamber 100. High frequency power is then applied to the upper and lower electrodes 140, 160 as soon as the process gas is supplied into the vessel 120 of the process chamber 100.

Thus, an electric field is formed between the upper electrode 140 and the lower electrode 160 and the process gas is converted to plasma by being activated by the electric field. Ions of the plasma etch the wafer 90 on the electrostatic chuck 162. At this time, the shield ring 144 and the insulation ring unit 170 will not be etched because they are coated with a protection layer, such as a layer of Al₂O₃, AlN, TiN or DLC.

As described above, the process chamber 100 in accordance with the present invention includes a shield ring 144 and an insulation ring unit 170 for insulating the upper and lower electrodes 140 and 160 from each other. Furthermore, the shield ring 144 and the insulation ring unit 170 are coated with a protection layer so as not to be etched during the etching of the wafer 90. Furthermore, particles are not generated because the outer vessel or the rings formed of quartz is/are not etched during the etching process, thereby preventing the operating rate from decreasing and wafer loss. Further, byproducts formed during the etching process in the process chamber 100 will not be deposited onto the shield ring 144 and the insulation ring unit 170 because the protection layers of the shield ring 144 and the insulation ring unit 170 prevent the deposition of the byproducts thereon. Accordingly, the wafer loss is greatly reduced and cost of cleaning the process chamber is lowered.

Although the present invention has been particularly shown and described with reference to the preferred embodiments thereof, various changes in form and details may be apparent to those skilled in the art. For example, the present invention has been described with respect to dry etching equipment; however, the present invention is not so limited. Rather, the present invention is applicable to all types of plasma processing equipment. Accordingly, the foregoing and other changes made to the preferred embodiments without departing from the true spirit and scope of the invention as defined by the appended claims.

What is claimed is:

1. A process chamber for use in fabricating semiconducotr devices, comprising:
a vessel into which a process gas is to be supplied;
an upper electrode disposed in an upper part of said vessel and to which power is to be applied;
a shield ring extending along an outer peripheral side surface of the upper electrode for insulating the upper electrode;
a lower electrode disposed under the upper electrode as spaced from the upper electrode and to which power is to be applied to convert the process gas to plasma;
an electrostatic chuck disposed on said lower electrode and on which a wafer is to be received; and
an insulation ring unit extending along an outer peipheral side surface of the lower electrode for insulating the lower electrode,
wherein said shield ring and said insulation ring unit each include a substrate, and a protection layer coating the substrate to prevent the shield ring and the insulation ring unit from being etched by the plasma.

2. The process chamber according to claim 1, wherein said protection layer is a layer of AlN.

3. The process chamber according to claim 1, whrein said protection layer is a layer of TiN.

4. The process chamber according to claim 1, whrein said protection layer is a diamond-like coating (DLC).

5. The protess chamber according to claim 1, wherein the protection layer is a layer of Al₂O₃.
